(19) United States
(12) Patent Application Publication
(10) Pub. No.: US 2008/0061393 A1
(43) Pub. Date: Mar. 13, 2008

(54) PHOTOSENSITIVE CHIP MOLDING PACKAGE

(75) Inventor: Tzu-Yin YEN, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/766,242

(22) Filed: Jun. 21, 2007

(30) Foreign Application Priority Data
Sep. 8, 2006 (TW) 95216096

(51) Int. Cl. H01L 31/0203

(52) U.S. Cl. 257/433; 257/E31.117

(57) ABSTRACT

A photosensitive chip molding package includes a lead frame, a photosensitive chip mounted on the lead frame and having an photo-active zone and a photo-inactive zone surrounding the photo-active zone, a plurality of bonding wires electrically connected with the photosensitive chip and the lead frame, and an encapsulant molded on the photo-inactive zone of the photosensitive chip and the lead frame. The encapsulant covers the photo-inactive zone, the bonding wires and a part of the lead frame to define an opening corresponding to the photo-active zone. The encapsulant is made of light-blocking material.

### BACKGROUND OF THE INVENTION

1. Field of the Invention

The present invention relates generally to photosensitive chip packages and more particularly, to a photosensitive chip package having a light-blocking encapsulant with an opening facing a photo-active zone of a photosensitive chip.

2. Description of the Related Art

Photosensitive chips are widely used in various different fields. To enhance the performance and stability of a photosensitive chip, mechanical support strength, environmental factors (such as light sources), electrical connection condition, heat resistivity, and many other factors must be taken into account during packaging.

In a known plastic packaging architecture for photosensitive chip, a transparent cap is used to cap on the photosensitive chip for guiding incident light to the photosensitive chip for detection. The manufacturing procedure of this design of photosensitive chip package is complicated, resulting in increase of manufacturing cost and time. Further, this design of photosensitive chip package is especially suitable for ball grid array (BGA) package by surface mount technology (SMT). Such limitation of this design of photosensitive chip package narrows its applicability.

There is known another design of photosensitive chip package, which uses a transparent encapsulant to package a photosensitive chip, forming a shell to enhance the structural strength. The transparent shell allows light to pass to the photosensitive chip. The manufacturing process of this design of photosensitive chip package is much simple. However, environmental light may pass through the transparent shell to interfere with the photosensitive chip, affecting the performance of the photosensitive chip, and lowering the detection reliability.

Therefore, it is desirable to provide a photosensitive chip package that can eliminate the aforesaid drawbacks.

### SUMMARY OF THE INVENTION

The present invention has been accomplished under the circumstances in view. It is therefore one objective of the present invention to provide a photosensitive chip molding package, which simplifies the manufacturing process, saves much the manufacturing cost and has a better applicability.

To achieve this objective of the present invention, the photosensitive chip molding package comprises a lead frame, a photosensitive chip, a plurality of bonding wires and an encapsulant. The photosensitive chip is mounted on the lead frame and has an photo-active zone and a photo-inactive zone surrounding the photo-active zone. The bonding wires are electrically connected with the photosensitive chip and the lead frame. The encapsulant is molded on the photo-inactive zone of the photosensitive chip and the lead frame. The encapsulant covers the photo-inactive zone of the photosensitive chip, the bonding wires and a part of the lead frame to define an opening corresponding to the photo-active zone. The encapsulant is made of light-blocking material.

The photosensitive chip molding package uses molding technology to substitute for conventional cap package or transparent package, simplifying the manufacturing process and saving much the manufacturing cost.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing the molding process of a photosensitive chip molding package in accordance with a first preferred embodiment of the present invention;

FIG. 2 is a schematic drawing showing the photosensitive chip molding package in accordance with the first preferred embodiment of the present invention;

FIG. 3 is a schematic drawing showing the molding process of a photosensitive chip molding package in accordance with a second preferred embodiment of the present invention, and

FIG. 4 is a schematic drawing showing a photosensitive chip molding package in accordance with the second preferred embodiment of the present invention.

### DETAILED DESCRIPTION OF THE INVENTION

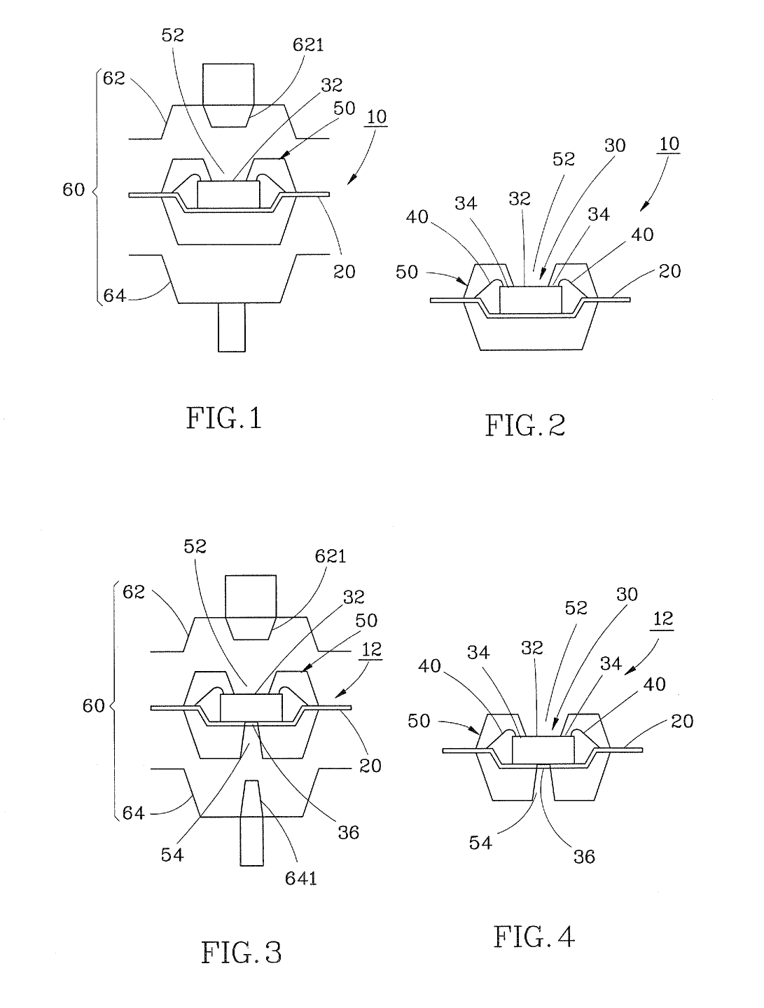

As shown in FIGS. 1 and 2, a photosensitive chip molding package 10 in accordance with a first preferred embodiment of the present invention comprises a lead frame 20, a photosensitive chip 30, a plurality of bonding wires 40 and an encapsulant 50.

The lead frame 20 is provided at the bottom side of the photosensitive chip 30 for supporting the photosensitive chip 30 and has a plurality of leads extending horizontally outwards.

The photosensitive chip 30 can be a CCD (charge-coupled device) chip, CMOS (Complementary metal oxide semiconductor) chip, or LED (light emitting diode) chip. According to this embodiment, the photosensitive chip 30 is preferably a CCD (charge-coupled device) chip. The photosensitive chip 30 has a photo-active zone 32 and a photo-inactive zone 34. The photo-active zone 32 is at the center of the photosensitive chip 30. The photo-inactive zone 34 surrounds the photo-active zone 32.

The bonding wires 40 are electrically connected between the top side of the photo-inactive zone 34 of the photosensitive chip 30 and the lead frame 20.

The encapsulant 50 is made of a light-blocking material molded on the lead frame 20 and the photo-inactive zone 34 of the photosensitive chip 30 and covering a part of the lead frame 20, the photo-inactive zone 34 and the bonding wires 40. The encapsulant 50 has an opening 52 at a top side thereof corresponding to the photo-active zone 32 so that light can pass through the opening 52 and fall on the photo-active zone 32. The encapsulant 50 is formed by means of molding technology through a mold 60. The mold 60 comprises an upper die 62 and a bottom die 64. The upper die 62 and the bottom die 64 are closeable to each other. The upper die 62 has a protruding portion 621 stoppable at the photo-active zone 32 to form the opening 52 at the top side of the encapsulant 50 when molding, as shown in FIG. 1.

Instead of conventional cap package or transparent package, the invention uses molding technology to seal the photo-inactive zone 34 of the photosensitive chip molding package 10. The opening 52 of the encapsulant 50 limits the detection range of the photosensitive chip 30, lowering the interference of environmental noises, i.e., the photosensitive chip molding package 10 has better stability. Further, the invention simplifies the manufacturing process, saving much time and labor. Further, the invention is applicable to small outline package (SOP), quad flat no-lead package (QFN), quad flat package (QFP), plastic dual in-line package (P-DIP), i.e., the invention has better applicability.

FIGS. 3 and 4 illustrate a photosensitive chip molding package 12 in accordance with a second preferred embodiment of the present invention. Similar to the aforesaid first preferred embodiment, the photosensitive chip molding package 12 comprises a lead frame 30, a photosensitive chip 30, a plurality of bonding wires 40 and an encapsulant 50. The difference between this second embodiment and the aforesaid first embodiment is that the photosensitive chip 30 further comprises a second photo-active zone 36 at the bottom side, and the encapsulant 50 has a second opening 54 formed at the bottom side corresponding to the second photo-active zone 36 of the photosensitive chip 30. According to this embodiment, the bottom die 64 of the mold 60 has a protruding portion 641 stoppable at the second photo-active zone 36 of the photosensitive chip 30 to form the second opening 54 at the bottom side of the encapsulant 50 when molding, as shown in FIG. 3.

The photosensitive chip molding package 12 of this second embodiment simply uses an alternate form of photosensitive chip 30. This second embodiment achieves the same effects as the aforesaid first embodiment.

As stated above, the invention uses molding technology to substitute for conventional cap package or transparent package, simplifying the manufacturing process, saving much the manufacturing cost and extending the applicability.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A photosensitive chip molding package comprising:
a lead frame;
a photosensitive chip mounted on the lead frame, the photosensitive chip having an photo-active zone and a photo-inactive zone surrounding the photo-active zone;
a plurality of bonding wires electrically connected with the photosensitive chip and the lead frame; and
an encapsulant, which is light-blocking, covering the photo-inactive zone of the photosensitive chip, the bonding wires and a part of the lead frame, and having an opening corresponding to the photo-active zone.

2. The photosensitive chip molding package as claimed in claim 1, wherein the encapsulant is formed by means of a mold through molding technology.

3. The photosensitive chip molding package as claimed in claim 2, wherein the mold comprises an upper die and a bottom die closeable to the upper die, and the mold has a protruding portion stoppable at the photo-active zone of the photo-sensitive chip when molding.

4. The photosensitive chip molding package as claimed in claim 3, wherein the upper die has the protruding portion to form the opening at a top side of the encapsulant.

5. The photosensitive chip molding package as claimed in claim 3, wherein the bottom die has the protruding portion to form the opening at a bottom side of the encapsulant.

6. The photosensitive chip molding package as claimed in claim 1, wherein the photosensitive chip is one of charge-coupled device chip, complementary metal oxide semiconductor chip and light emitting diode chip.
